(19) United States
(12) Patent Application Publication
(10) Pub. No.: US 2025/0015093 A1
(43) Pub. Date: Jan. 9, 2025

(54) CONNECTION STRUCTURE, DISPLAY PANEL, MANUFACTURING METHOD, DETECTION CIRCUITRY, AND DISPLAY DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Xiaojuan GAO, Beijing (CN); Boning WANG, Beijing (CN); Litao FAN, Beijing (CN); Yangli ZHENG, Beijing (CN); Jian REN, Beijing (CN); Xiaoping ZHANG, Beijing (CN); Gaowei CHEN, Beijing (CN); Fangyi LIU, Beijing (CN); Shuqian DOU, Beijing (CN); Yaodong WANG, Beijing (CN); Jian ZHANG, Beijing (CN); Zhenguo ZHOU, Beijing (CN); Naiqi MEN, Beijing (CN); Luo ZHANG, Beijing (CN); Yingxue YU, Beijing (CN); Siqi YIN, Beijing (CN)

(21) Appl. No.: 18/546,693

(22) PCT Filed: Sep. 1, 2022
(86) PCT No.: PCT/CN2022/116458

§ 371 Date: Aug. 16, 2023

(51) Int. Cl. H01L 27/12; H01L 25/16

(52) U.S. Cl. CPC H01L 27/124; H01L 25/167

(57) ABSTRACT

The present disclosure provides a connection structure, a display panel, a manufacturing method, a detection circuitry and a display device. The connection structure includes a connection unit. The connection unit includes a first connection member, a second connection member, and a binding member. The first connection member includes a plurality of first connectors, the second connection member includes a plurality of second connectors, the binding member includes a plurality of binding pins, the connection unit includes a plurality of metal layers and a plurality of insulation layers, the second connector includes a second connection line, the second connection line includes at least two second connection line portions electrically coupled to each other, and at least two insulation layers in the connection unit are arranged on a side of the at least two metal layers away from the base substrate.

### TECHNICAL FIELD

The present disclosure relates to the field of display technology, in particular to a connection structure, a display panel, a manufacturing method, a detection circuitry, and a display device.

### BACKGROUND

Currently, as a mainstream trend, a screen-to-body ratio of a mobile phone is increased so as to improve the user experience. A narrow border plays a very important role in increasing the screen-to-body ratio. A scheme for providing a narrower border has been proposed, but when a Flexible Circuitry Board (FPC) On Glass (FOG) is bound, there is a risk of short circuitry between an FPC bump line and panel wiring.

### SUMMARY

In one aspect, the present disclosure provides in some embodiments a connection structure electrically coupled to an input pin of a display driver integrated circuitry, including a connection unit. The connection unit includes a first connection member, a second connection member, and a binding member arranged on a base substrate; the first connection member includes a plurality of first connectors, the second connection member includes a plurality of second connectors, the binding member includes a plurality of binding pins, the input pin is electrically coupled to the second connector through the first connector, the second connector is electrically coupled to the binding pin, the connection unit includes a plurality of metal layers and a plurality of insulation layers, the second connector includes a second connection line, the second connection line includes at least two second connection line portions electrically coupled to each other, the at least two second connection line portions are formed by at least two metal layers in the plurality of metal layers respectively, and at least two insulation layers in the connection unit are arranged on a side of the at least two metal layers away from the base substrate.

In a possible embodiment of the present disclosure, the first connector includes a first connection line, the first connection line includes at least two first connection line portions electrically coupled to each other, the at least two first connection line portions are formed by at least two metal layers of the plurality of metal layers respectively, and the first connection line is electrically coupled to the second connection line.

In a possible embodiment of the present disclosure, the first connection line further includes at least one first connection line portion, all the first connection line portions of the first connection line are electrically coupled to each other, and the at least one first connection line portion is formed by at least one metal layer in the plurality of metal layers other than the at least two metal layers.

In a possible embodiment of the present disclosure, the connection unit includes a first metal layer, a first insulation layer, a second metal layer, a second insulation layer, a third metal layer and a third insulation layer arranged one on another along a direction away from the base substrate, the second connection line includes a first one of second connection line portions and a second one of second connection line portions electrically coupled to each other, the first one of second connection line portions is formed by the first metal layer, and the second one of second connection line portions is formed by the second metal layer.

In a possible embodiment of the present disclosure, a thickness of the first insulation layer is greater than 3000 angstroms and less than or equal to 4000 angstroms, a thickness of the second insulation layer is greater than or equal to 4000 angstroms and less than or equal to 6000 angstroms, and a thickness of the third insulation layer is greater than or equal to 600 angstroms and less than or equal to 2000 angstroms.

In a possible embodiment of the present disclosure, the first connector includes a first connection line, the first connection line includes a first one of first connection line portions and a second one of first connection line portions electrically coupled to each other, the first one of first connection line portions is formed by the first metal layer, the second one of first connection line portions is formed by the second metal layer, the first one of first connection line portions is electrically coupled to the first one of second connection line portions, and the second one of first connection line portions is electrically coupled to the second one of second connection line portions.

In a possible embodiment of the present disclosure, the first connection line further includes a third one of first connection line portions, the third one of first connection line portions is electrically coupled to the first one of first connection line portions and the second one of first connection line portions, and the third one of first connection line portions is formed by the third metal layer.

In a possible embodiment of the present disclosure, the first metal layer is a shielding layer, the second metal layer is a gate metal layer, and the third metal layer is a source/drain metal layer.

In a possible embodiment of the present disclosure, the first insulation layer includes a buffer layer and a gate insulation layer arranged one on another along a direction away from the base substrate, the second insulation layer is an interlayer dielectric layer, and the third insulation layer is a passivation layer.

In a possible embodiment of the present disclosure, the binding pin includes a binding connection line electrically coupled to the second connection line and including a first binding connection line portion and a second binding connection line portion electrically coupled to each other, the first binding connection line portion is formed by the second metal layer, and the second binding connection line portion is formed by the third metal layer.

In a possible embodiment of the present disclosure, an extension direction of the binding pin is a first direction, and a length of the second connector along the first direction is greater than 0.07 mm and less than or equal to 0.09 mm.

In another aspect, the present disclosure provides in some embodiments a display substrate including the above-mentioned connection structure.

In yet another aspect, the present disclosure provides in some embodiments a display panel including the above-mentioned display substrate.

In a possible embodiment of the present disclosure, the display panel further includes a flexible circuitry board, and pins of the flexible circuitry board are bound to binding pins.

In a possible embodiment of the present disclosure, a distance between a first edge of each pin of the flexible circuitry board and a cutting edge of the flexible circuitry board is greater than or equal to 10 μm and less than or equal to 30 μm, the first edge is an edge of the pin close to the cutting edge, and the cutting edge is an edge of the flexible circuitry board closest to the first connection member.

In still yet another aspect, the present disclosure provides in some embodiments a method for manufacturing the above-mentioned display panel, including enabling a flexible circuitry board to be bound to a display substrate through a binding pressure head.

In a possible embodiment of the present disclosure, a buffer material layer is arranged between the binding pressure head and the flexible circuitry board, and a thickness of the buffer material layer is greater than or equal to 100 μm and smaller than or equal to 150 μm.

In still yet another aspect, the present disclosure provides in some embodiments a detection circuitry for the above-mentioned display panel, including a detection line and a detection unit. The detection line is electrically coupled to a to-be-detected binding pin, and the detection unit is electrically coupled to the detection line and configured to determine where a short circuit occurs for the to-be-detected binding pin in accordance with a voltage across the detection line.

In a possible embodiment of the present disclosure, the detection unit includes a light-emitting diode, an anode of the light-emitting diode is electrically coupled to the detection line, and a cathode of the light-emitting diode is electrically coupled to a detection comparison voltage end, so as to determine whether the short circuit occurs for the to-be-detected binding pin in accordance with whether the light-emitting diode emits lights. The detection comparison voltage end is configured to output a corresponding detection comparison voltage in accordance with the to-be-detected binding pin.

In still yet another aspect, the present disclosure provides in some embodiments a display device including the above-mentioned display panel.

### BRIEF DESCRIPTION OF THE DRAWINGS

FIG. 1A is a schematic view showing a connection structure according to one embodiment of the present disclosure:

FIG. 1B is another schematic view showing the connection structure according to one embodiment of the present disclosure:

FIG. 2 is a sectional view of the connection structure along line A-A″ in FIG. 1B:

FIG. 3 is a sectional view of the connection structure along line B-B″ in FIG. 1B:

FIG. 4 is yet another schematic view showing the connection structure according to one embodiment of the present disclosure:

FIG. 5 is another sectional view of the connection structure along line A-A″ in FIG. 1B:

FIG. 6 is an equivalent impedance diagram of the connection structure in FIG. 5:

FIG. 7 is another sectional view of the connection structure along line B-B″ in FIG. 1B:

FIG. 8 is a sectional view of the connection structure along line D-D′ in FIG. 1B:

FIG. 9 is a sectional view of the connection structure along line C-C″ in FIG. 1B:

FIG. 10 is a schematic view showing a flexible circuitry board in a display panel according to one embodiment of the present disclosure;

FIG. 11 is a schematic view showing a situation where the flexible circuitry board is bound to a display substrate according to one embodiment of the present disclosure:

FIG. 12 is a schematic view showing a detection circuitry according to one embodiment of the present disclosure; and

FIG. 13 is a circuit diagram of the detection circuitry according to one embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

The present disclosure provides in some embodiments a connection structure electrically coupled to an input pin of a display driver integrated circuitry, which includes a connection unit. The connection unit includes a first connection member, a second connection member, and a binding member arranged on a base substrate: the first connection member includes a plurality of first connectors, the second connection member includes a plurality of second connectors, the binding member includes a plurality of binding pins, the input pin is electrically coupled to the second connector through the first connector, the second connector is electrically coupled to the binding pin, the connection unit includes a plurality of metal layers and a plurality of insulation layers, the second connector includes a second connection line, the second connection line includes at least two second connection line portions electrically coupled to each other, the at least two second connection line portions are formed by at least two metal layers in the plurality of metal layers respectively, and at least two insulation layers in the connection unit are arranged on a side of the at least two metal layers away from the base substrate.

According to the connection structure in the embodiments of the present disclosure, the second connection member includes the plurality of second connectors, each second connector includes the second connection line, the second connection line includes at least two second connection line portions electrically coupled to each other and formed by the at least two metal layers in the plurality of metal layers respectively, and at least two insulation layers are arranged on a side of the at least two metal layers away from the base substrate. As a result, a plurality of insulation layers is arranged above the second connection line, so it is able to prevent the second connection line from being damaged when a pin of a flexible circuitry board is bound to the binding pin.

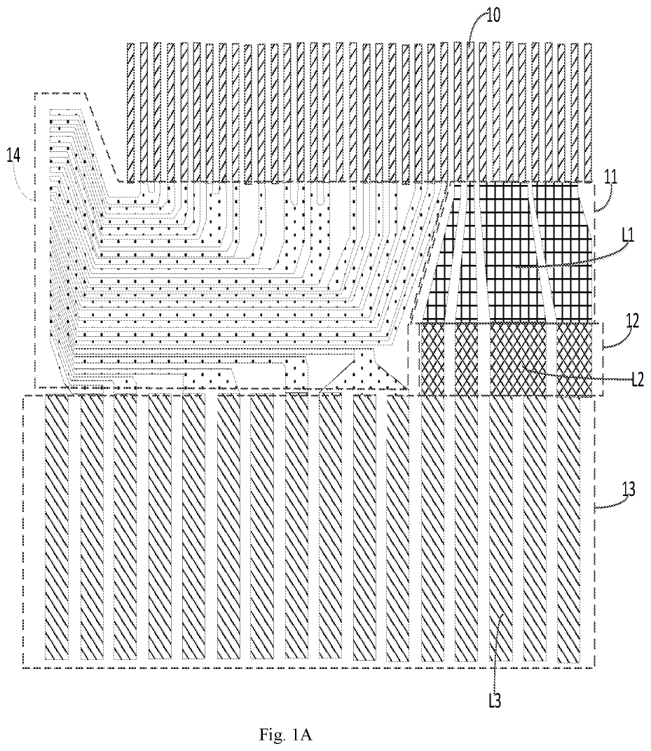

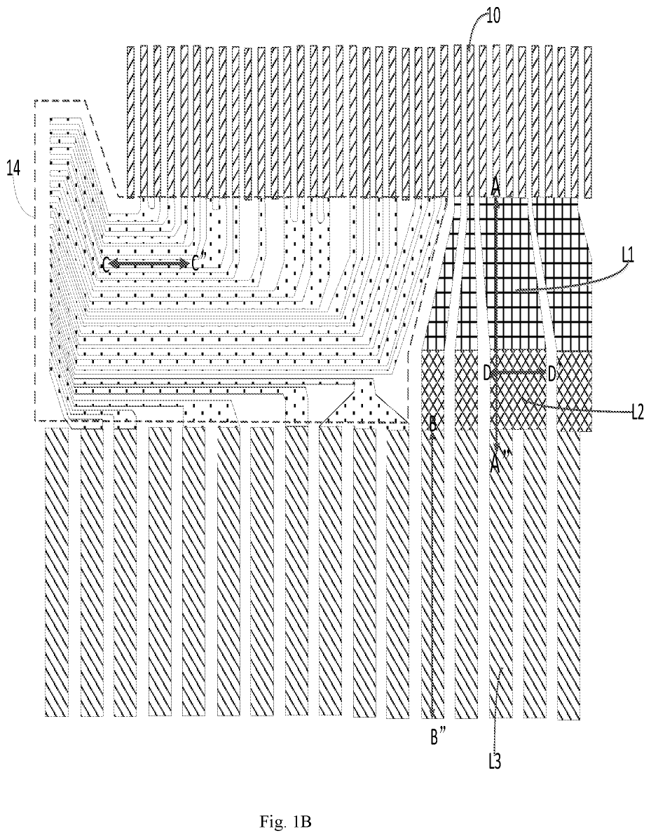

In FIG. 1A, 10 is the input pin of the display driver integrated circuitry, 11 is the first connection member, 12 is the second connection member, 13 is a binding member, L1 is the first connector, L2 is a second connector, and L3 is the binding pin.

In the related art, when a pin of a flexible circuitry board is bound to the binding pin, due to the binding accuracy, the pin of the flexible circuitry board may be bound to the second connector, and the second connection line may be damaged. In the embodiments of the present disclosure, the at least two second connection line portions are formed by the at least two metal layers in the plurality of metal layers respectively, and at least two insulation layers are arranged on a side of the at least two metal layers away from the base substrate. Through the plurality of insulation layers, it is able to protect the second connection line.

In the embodiments of the present disclosure, the pin of the flexible circuitry board is a golden finger bump.

In FIG. 1A, 14 is a third connection member. At least a part of the third connectors of the third connection member are connectors between the input pin and an element or a signal end of a display substrate, and the remaining part of the third connectors are connectors between the pin of the flexible circuitry board and an element or signal end of the display substrate. Each third connector includes a third connection line.

In the embodiments of the present disclosure, the first connector includes a first connection line, the first connection line includes at least two first connection line portions electrically coupled to each other, the at least two first connection line portions are formed by at least two metal layers of the plurality of metal layers respectively, and the first connection line is electrically coupled to the second connection line.

During the implementation, the first connector includes the first connection line, the first connection line includes at least two first connection line portions electrically coupled to each other, the at least two first connection line portions are formed by at least two metal layers in the plurality of metal layers respectively, and the first connection line is electrically coupled to the second connection line, so as to enable input pin of the display driver integrated circuitry to be electrically coupled to the pin of the flexible circuitry board.

In a possible embodiment of the present disclosure, the first connection line further includes at least one first connection line portion, all the first connection line portions of the first connection line are electrically coupled to each other, and the at least one first connection line portion is formed by at least one metal layer in the plurality of metal layers other than the at least two metal layers.

In the embodiments of the present disclosure, the first connection line further includes at least one first connection line portion, the first connection line portions are electrically coupled to each other, and the at least one first connection line portion is formed by at least one metal layer in the plurality of metal layers other than the at least two metal layers. In this way, it is able to reduce the impedance through forming the lines in multiple layers and in parallel to each other, and prevent the lines from being damaged.

In the embodiments of the present disclosure, the connection unit includes a first metal layer, a first insulation layer, a second metal layer, a second insulation layer, a third metal layer and a third insulation layer arranged one on another along a direction away from the base substrate, the second connection line includes a first one of second connection line portions and a second one of second connection line portions electrically coupled to each other, the first one of second connection line portions is formed by the first metal layer, and the second one of second connection line portions is formed by the second metal layer.

During the implementation, the connection unit includes the first metal layer, the first insulation layer, the second metal layer, the second insulation layer, the third metal layer and the third insulation layer arranged one on another along the direction away from the base substrate, the first one of second connection line portions is formed by the first metal layer, the second one of second connection line portions is formed by the second metal layer, and the second insulation layer and the third insulation layer are arranged on the second metal layer. Through second insulation layer and the third insulation layer, it is able to protect the second connection line from being damaged.

In a possible embodiment of the present disclosure, a thickness of the first insulation layer is greater than 3000 angstroms and less than or equal to 4000 angstroms, a thickness of the second insulation layer is greater than or equal to 4000 angstroms and less than or equal to 6000 angstroms, and a thickness of the third insulation layer is greater than or equal to 600 angstroms and less than or equal to 2000 angstroms.

In a possible embodiment of the present disclosure, the first connector includes a first connection line, the first connection line includes a first one of first connection line portions and a second one of first connection line portions electrically coupled to each other, the first one of first connection line portions is formed by the first metal layer, the second one of first connection line portions is formed by the second metal layer, the first one of first connection line portions is electrically coupled to the first one of second connection line portions, and the second one of first connection line portions is electrically coupled to the second one of second connection line portions.

During the implementation, the first connector includes the first connection line, the first connection line includes the first one of first connection line portions and the second one of first connection line portions electrically coupled to each other, the first one of first connection line portions and the first one of second connection line portions are both formed on the first metal layer, the second one of first connection line portions and the second one of second connection line portions are both formed on the second metal layer, and the first connection line portion and the second connection line portion on the same metal layer are electrically coupled to each other.

In a possible embodiment of the present disclosure, the first connection line further includes a third one of first connection line portions, the third one of first connection line portions is electrically coupled to the first one of first connection line portions and the second one of first connection line portions, and the third one of first connection line portions is formed by the third metal layer.

During the implementation, the third one of first connection line portions is formed by the third metal layer and electrically coupled to the first one of first connection line portions and the second one of first connection line portions. In this way, the first connection line is formed through three first connection line portions arranged on different layers and in parallel to each other, so as to reduce the impedance.

In a possible embodiment of the present disclosure, the first metal layer is a shielding layer, the second metal layer is a gate metal layer, and the third metal layer is a source/drain metal layer.

In the embodiments of the present disclosure, an impedance of the gate metal layer is greater than an impedance of the shielding layer, and the impedance of the shielding layer is greater than an impedance of the source/drain metal layer.

In the embodiments of the present disclosure, the shielding layer is made of Mo or Al.

In a possible embodiment of the present disclosure, the first insulation layer includes a buffer layer and a gate insulation layer arranged one on another along a direction away from the base substrate, the second insulation layer is an interlayer dielectric layer, and the third insulation layer is a passivation layer.

In a possible embodiment of the present disclosure, the binding pin includes a binding connection line electrically coupled to the second connection line and including a first binding connection line portion and a second binding connection line portion electrically coupled to each other, the first binding connection line portion is formed by the second metal layer, and the second binding connection line portion is formed by the third metal layer.

During the implementation, the binding pin includes the binding connection line, the binding connection line includes the first binding connection line portion and the second binding connection line portion electrically coupled to each other, the first binding connection line portion is formed by the second metal layer, and the second binding connection line portion is formed by the third metal layer.

In a possible embodiment of the present disclosure, an extension direction of the binding pin is a first direction, and a length of the second connector along the first direction is greater than 0.07 mm and less than or equal to 0.09 mm.

In the embodiments of the present disclosure, the first direction is, but not limited to, a vertical direction.

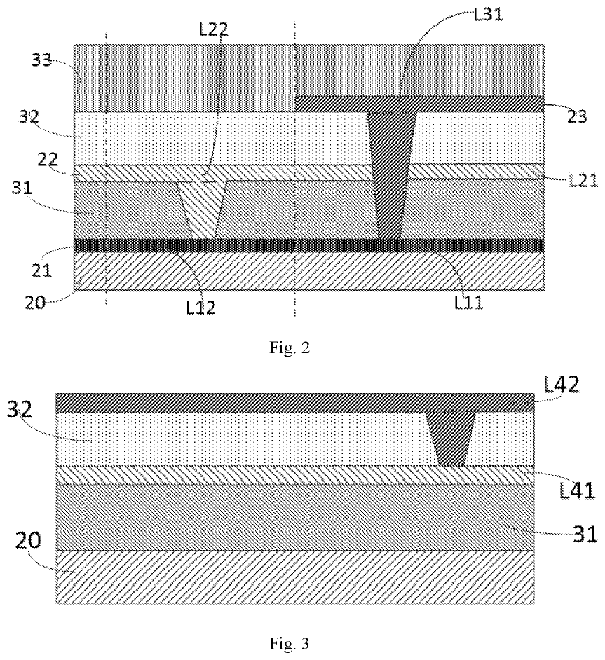

FIG. 2 is a sectional view of the connection structure along line A-A″ in FIG. 1B.

In FIG. 2, 20 is the base substrate, 21 is the first metal layer, 31 is the first insulation layer, 22 is the second metal layer, 32 is the second insulation layer, 23 is the third metal layer, 33 is the third insulation layer, L11 is the first one of first connection line portions, L21 is the second one of first connection line portions, L31 is the third one of first connection line portions, L11, L21, and L31 are electrically coupled to each other, L11 is formed on the first metal layer 21, L21 is formed on the second metal layer 22, L31 is formed on the third metal layer 23, L12 is the first one of second connection line portions, L22 is the second one of second connection line portions, L12 and L22 are electrically coupled to each other, L12 is formed on the first metal layer 21, L22 is formed on the second metal layer 22, L11 is electrically coupled to L12, and L21 is electrically coupled to L22.

In FIG. 2, the second connection line includes the first one of second connection line portions L12 formed on the first metal layer 21 and the second one of second connection line portions L22 formed on the second metal layer 22, the second metal layer 22 is arranged on the side of the first metal layer 21 away from the base substrate, and the second insulation layer 32 and the third insulation layer 33 are arranged on a side of the second metal layer 22 away from the base substrate. In this way, it is able to prevent the second one of second connection line portion L22 from being damaged.

In FIG. 2, the first connection line includes the first one of first connection line portions L11 formed on the first metal layer 21, the second one of first connection line portions L21 formed on the second metal layer 22, and the third one of first connection line portions L31 formed on the third metal layer 23. In this way, the first connection lines includes three connection line portions arranged on different layers and in parallel to each other, so as to reduce the impedance.

FIG. 3 is a sectional view of the connection structure along line B-B″ in FIG. 1B.

In FIG. 3, 20 is the base substrate, 31 is the first insulation layer, 32 is the second insulation layer, L41 is the first binding connection line portion, and L42 is the second binding connection line portion. The first binding connection line portion L41 is formed on the second metal layer, the second binding connection line portion L42 is formed on the third metal layer, and L41 and L42 are electrically coupled to each other.

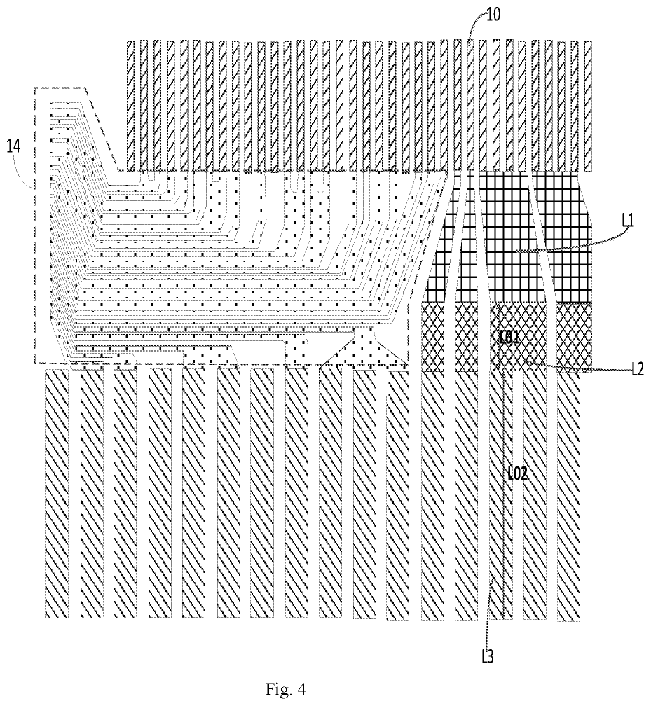

As shown in FIG. 4, on the basis of the connection structure in FIG. 1A, a length L01 of the second connector L2 in the vertical direction is, but not limited to, 0.08 mm, and a length L02 of the binding pin L3 in the vertical direction is, but not limited to, 0.3 mm.

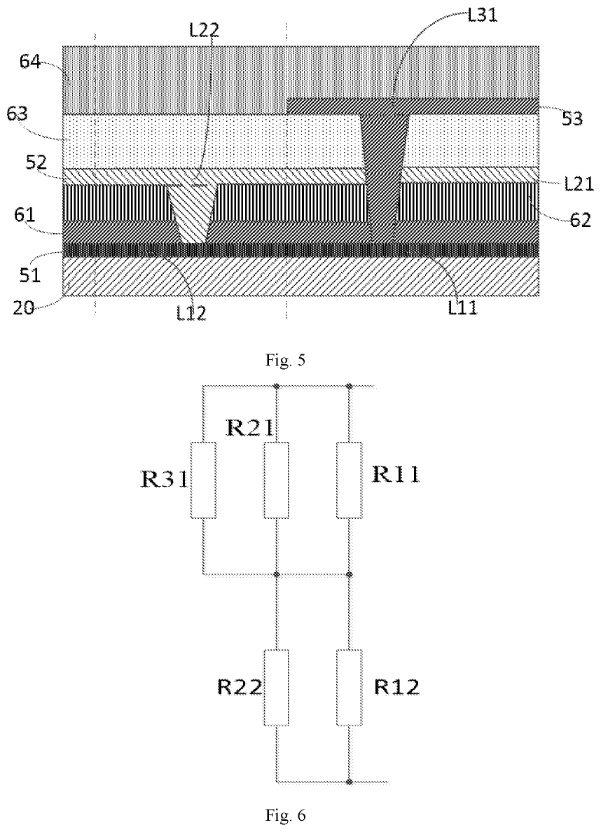

When the first metal layer is a shielding layer, the second metal layer is a gate metal layer and the third metal layer is a source/drain metal layer, the first insulation layer includes a buffer layer and a gate insulation layer arranged one on another along a direction away from the base substrate. When the second insulation layer is an interlayer dielectric layer and the third insulation layer is a passivation layer, FIG. 5 shows a cross section of the connection structure along line A-A″ in FIG. 1B.

In FIG. 5, 20 is the base substrate, 51 is the shielding layer, 61 is the buffer layer, 62 is the gate insulation layer, 52 is the gate metal layer, 63 is the interlayer dielectric layer, 53 is the source/drain metal layer, and 64 is the passivation layer.

In FIG. 5, L11 is the first one of first connection line portions, L21 is the second one of first connection line portions, L31 is the third one of first connection line portions, and L11, L21 and L31 are electrically coupled to each other. L11 is formed on the shielding layer 51, L21 is formed on the gate metal layer 52, and L31 is formed on the source/drain metal layer 53.

In FIG. 5, L12 is the first one of second connection line portions, L22 is the second one of second connection line portions, and L12 and L22 are electrically coupled to each other. L12 is formed on the shielding layer 51, L22 is formed on the gate metal layer 52, L11 is electrically coupled to L12, and L21 is electrically coupled to L22.

In FIG. 5, the second connection line includes the first one of second connection line portions L12 formed on the shielding layer 51 and the second one of second connection line portions L22 formed on the gate metal layer 52, the gate metal layer 52 is arranged on a side of the shielding layer 51 away from the base substrate 20, and the interlayer dielectric layer 63 and the passivation layer 64 are arranged on a side of the gate metal layer 52 away from the base substrate 20. In this way, it is able to prevent the second one of second connection line portions L22 from being damaged.

In FIG. 5, the first connection line includes the first one of first connection line portions L11 on the shielding layer 51, the second one of first connection line portions L21 on the gate metal layer 52, and the third one of first connection line portions L31 on the source/drain metal layer 53. Through the three connection line portions arranged on different layers and in parallel to each other, it is able to reduce the impedance and prevent the line from being damaged.

In the embodiments of the present disclosure, the impedance of the gate metal layer 52 is greater than the impedance of the shielding layer 51, and the impedance of the shielding layer 51 is greater than the impedance of the source/drain metal layer 53. When the line is formed on the shielding layer rather than the source/drain metal layer, the entire impedance of the line may increase. In the embodiments of the present disclosure, at an end close to the flexible printed circuitry (FPC), the line is formed on the gate metal layer and the shielding layer, and the first connection member includes three portions formed on the source/drain metal layer, the gate metal layer and the shielding layer and arranged in parallel to each other. In this way, it is able to reduce the impedance and prevent the line from being damaged.

FIG. 6 is an equivalent impedance diagram of the connection structure in FIG. 5.

In FIG. 6, R11 is an equivalent impedance of L11, R21 is an equivalent impedance of L21, R31 is an equivalent impedance of L31, R12 is the equivalent impedance of L12, and R22 is the equivalent impedance of L22.

When the first metal layer is a shielding layer, the second metal layer is a gate metal layer and the third metal layer is a source/drain metal layer, the first insulation layer includes a buffer layer and a gate insulation layer arranged one on another along a direction away from the base substrate. When the second insulation layer is an interlayer dielectric layer and the third insulation layer is a passivation layer, FIG. 7 shows a cross section of the connection structure along line B-B″ in FIG. 1B.

In FIG. 7, 20 is the base substrate, 61 is the buffer layer, 62 is the gate insulation layer, and 63 is the interlayer dielectric layer.

In FIG. 7, L41 is the first binding connection line portion, and L42 is the second binding connection line portion. The first binding connection line portion L41 is formed on the gate metal layer, and the second binding connection line portion L42 is formed on the source/drain metal layer. L41 and L42 are electrically coupled to each other.

In FIG. 7, the second binding connection line portion L42 needs to be bound to, and thereby electrically coupled to, the pin of the flexible circuitry board, so no insulation layer is arranged on a side of the second binding connection line portion L42 away from the base substrate 20.

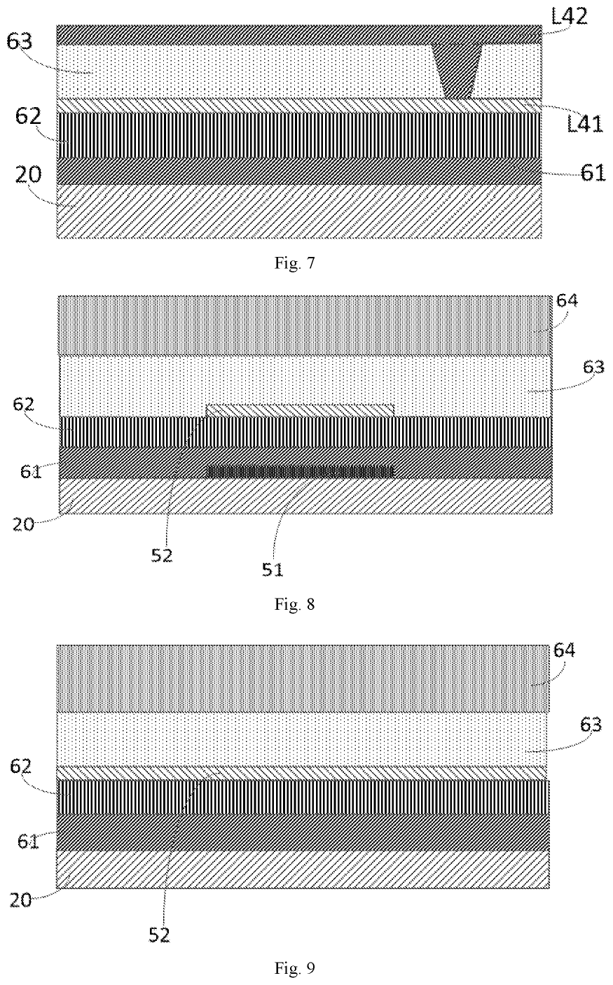

When the first metal layer is a shielding layer, the second metal layer is a gate metal layer and the third metal layer is a source/drain metal layer, the first insulation layer includes a buffer layer and a gate insulation layer arranged one on another along a direction away from the base substrate. When the second insulation layer is an interlayer dielectric layer, and the third insulation layer is a passivation layer, FIG. 8 shows a cross section of the connection structure along line D-D′ in FIG. 1B.

In FIG. 8, 20 is the base substrate, 51 is the shielding layer, 61 is the buffer layer, 62 is the gate insulation layer, 52 is the gate metal layer, 63 is the interlayer dielectric layer, and 64 is the passivation layer.

In FIG. 8, the first one of second connection line portions is formed on the shielding layer 51 and the second one of second connection line portions is formed on the gate metal layer 52.

When the first metal layer is a shielding layer, the second metal layer is a gate metal layer and the third metal layer is a source/drain metal layer, the first insulation layer includes a buffer layer and a gate insulation layer arranged one on another along a direction away from the base substrate. When the second insulation layer is an interlayer dielectric layer and the third insulation layer is a passivation layer, FIG. 9 is a cross section of the connection structure along line C-C″ in FIG. 1B.

In FIG. 9, 20 is the base substrate, 61 is the buffer layer, 62 is the gate insulation layer, 52 is the gate metal layer, 63 is the interlayer dielectric layer, and 64 is the passivation layer.

In FIG. 9, the third connection member includes a third connection line formed on the gate metal layer 52.

The present disclosure further provides in some embodiments a display substrate including the above-mentioned connection structure.

The present disclosure further provides in some embodiments a display panel including the above-mentioned display substrate.

The display panel further includes a flexible circuitry board, and pins of the flexible circuitry board are bound to binding pins.

In a possible embodiment of the present disclosure, a distance between a first edge of each pin of the flexible circuitry board and a cutting edge of the flexible circuitry board is greater than or equal to 10 μm and less than or equal to 30 μm, the first edge is an edge of the pin close to the cutting edge, and the cutting edge is an edge of the flexible circuitry board closest to the first connection member.

In the embodiments of the present disclosure, the distance between the first edge and the cutting edge is a shortest distance between the first edge and the cutting edge.

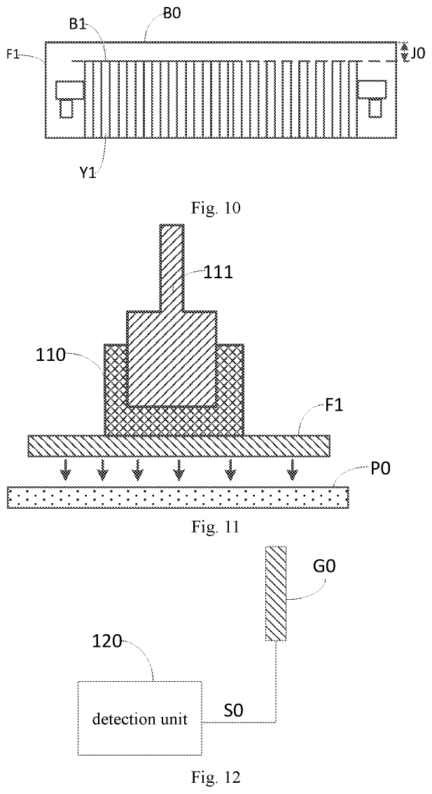

In FIG. 10, F1 is the flexible circuitry board, Y1 is a pin of the flexible circuitry board F1, B0 is the cutting edge, B1 is the first edge of the pin Y1, and J1 is a distance in the vertical direction between B1 and B0.

In the embodiments of the present disclosure, J1 is greater than or equal to 10 μm and less than or equal to 30 μm.

During the implementation, when the pin of the flexible circuitry board is bound to the binding pin, the cutting edge is closer to the input pins of the display driver integrated circuitry.

When the cutting edge is closer to the input pin, it means that the flexible circuitry board also has another edge arranged opposite to the cutting edge, and the distance between the cutting edge and the input pin is less than a distance between the edge and the input pin.

In the embodiments of the present disclosure, a length of the second connector in the first direction is greater than 0.07 mm and less than or equal to 0.09 mm, e.g., 0.08 mm. However, there is a tolerance of ±100 μm when binding the pin of the flexible circuitry board to the binding pin. In the embodiments of the present disclosure, the distance between the first edge of each pin of the flexible circuitry board and the cutting edge of the flexible circuitry board is set as 20 μm, so as to prevent the occurrence of the above-mentioned problems. The FPC is hollowed out at the edge, so as to prevent each pin of the flexible circuitry board from overlapping with the line of the display substrate.

The present disclosure further provides in some embodiments a method for manufacturing the above-mentioned display panel, which includes enabling a flexible circuitry board to be bound to a display substrate through a binding pressure head.

In a possible embodiment of the present disclosure, a buffer material layer is arranged between the binding pressure head and the flexible circuitry board, and a thickness of the buffer material layer is greater than or equal to 100 μm and smaller than or equal to 150 μm.

During the implementation, the thickness of the buffer material layer between the binding pressure head and the flexible circuitry board is set to be greater than or equal to 100 μm and less than or equal to 150 μm. In this way, it is able to reduce a pressure applied by the FPC onto the display substrate, thereby to prevent the display substrate from being damaged.

In FIG. 11, F1 is the flexible circuitry board, PO is the display substrate, 110 is the buffer material layer, and 111 is the binding pressure head.

The present disclosure further provides in some embodiments a detection circuitry for the above-mentioned display panel which, as shown in FIG. 12, includes a detection line S0 and a detection unit 12. The detection line S0 is electrically coupled to a to-be-detected binding pin GO, and the detection unit 120 is electrically coupled to the detection line S0 and configured to determine where a short circuit occurs for the to-be-detected binding pin GO in accordance with a voltage across the detection line S0.

The detection circuitry in the embodiments of the present disclosure is used to detect a short circuit in the case of a pattern generation test of the FOG.

In a possible embodiment of the present disclosure, the detection unit includes a light-emitting diode, an anode of the light-emitting diode is electrically coupled to the detection line, and a cathode of the light-emitting diode is electrically coupled to a detection comparison voltage end, so as to determine whether the short circuit occurs for the to-be-detected binding pin in accordance with whether the light-emitting diode emits lights. The detection comparison voltage end is configured to output a corresponding detection comparison voltage in accordance with the to-be-detected binding pin.

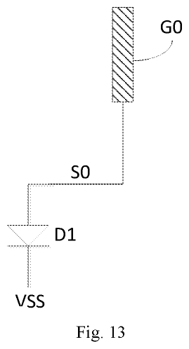

As shown in FIG. 13, when the to-be-detected binding pin GO is used to provide a low voltage signal VSS and the binding pin adjacent to the to-be-detected binding pin GO is used to provide a high voltage signal, the detection unit includes a light-emitting diode DI, an anode of DI is electrically coupled to the detection line S0, and a cathode of DI is configured to receive the low voltage signal VSS. When DI emits light, it means that a short circuit occurs between the to-be-detected binding pin GO and the binding pin adjacent thereto, and when DI does not emit light, it means that no short circuit occurs for the to-be-detected binding pin GO.

The present disclosure further provides in some embodiments a display device including the above-mentioned display panel.

The display device may be any product or member having a display function, e.g., mobile phone, tablet computer, television, display, laptop computer, digital photo frame or navigator.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A connection structure electrically coupled to an input pin of a display driver integrated circuitry, comprising a connection unit, wherein the connection unit comprises a first connection member, a second connection member, and a binding member arranged on a base substrate;
wherein the first connection member comprises a plurality of first connectors, the second connection member comprises a plurality of second connectors, the binding member comprises a plurality of binding pins, the input pin is electrically coupled to the second connector through the first connector, the second connector is electrically coupled to the binding pin, the connection unit comprises a plurality of metal layers and a plurality of insulation layers, the second connector comprises a second connection line, the second connection line comprises at least two second connection line portions electrically coupled to each other, the at least two second connection line portions are formed by at least two metal layers in the plurality of metal layers respectively, and at least two insulation layers in the connection unit are arranged on a side of the at least two metal layers away from the base substrate.

2. The connection structure according to claim 1, wherein the first connector comprises a first connection line, the first connection line comprises at least two first connection line portions electrically coupled to each other, the at least two first connection line portions are formed by at least two metal layers of the plurality of metal layers respectively, and the first connection line is electrically coupled to the second connection line.

3. The connection structure according to claim 2, wherein the first connection line further comprises at least one first connection line portion, and all the first connection line portions of the first connection line are electrically coupled to each other, and the at least one first connection line portion is formed by at least one metal layer in the plurality of metal layers other than the at least two metal layers.

4. The connection structure according to claim 1, wherein the connection unit comprises a first metal layer, a first insulation layer, a second metal layer, a second insulation layer, a third metal layer and a third insulation layer arranged one on another along a direction away from the base substrate, the second connection line comprises a first one of second connection line portions and a second one of second connection line portions electrically coupled to each other, the first one of second connection line portions is formed by the first metal layer, and the second one of second connection line portions is formed by the second metal layer.

5. The connection structure according to claim 4, wherein a thickness of the first insulation layer is greater than 3000 angstroms and less than or equal to 4000 angstroms, a thickness of the second insulation layer is greater than or equal to 4000 angstroms and less than or equal to 6000 angstroms, and a thickness of the third insulation layer is greater than or equal to 600 angstroms and less than or equal to 2000 angstroms.

6. The connection structure according to claim 4, wherein the first connector comprises a first connection line, the first connection line comprises a first one of first connection line portions and a second one of first connection line portions electrically coupled to each other, the first one of first connection line portions is formed by the first metal layer, the second one of first connection line portions is formed by the second metal layer, the first one of first connection line portions is electrically coupled to the first one of second connection line portions, and the second one of first connection line portions is electrically coupled to the second one of second connection line portions.

7. The connection structure according to claim 6, wherein the first connection line further comprises a third one of first connection line portions, the third one of first connection line portions is electrically coupled to the first one of first connection line portions and the second one of first connection line portions, and the third one of first connection line portions is formed by the third metal layer.

8. The connection structure according to claim 4, wherein the first metal layer is a shielding layer, the second metal layer is a gate metal layer, and the third metal layer is a source/drain metal layer.

9. The connection structure according to claim 8, wherein the first insulation layer comprises a buffer layer and a gate insulation layer arranged one on another along a direction away from the base substrate, the second insulation layer is an interlayer dielectric layer, and the third insulation layer is a passivation layer.

10. The connection structure according to claim 4, wherein the binding pin comprises a binding connection line electrically coupled to the second connection line and comprising a first binding connection line portion and a second binding connection line portion electrically coupled to each other, the first binding connection line portion is formed by the second metal layer, and the second binding connection line portion is formed by the third metal layer.

11. The connection structure according to claim 1, wherein an extension direction of the binding pin is a first direction, and a length of the second connector along the first direction is greater than 0.07 mm and less than or equal to 0.09 mm.

12. A display substrate, comprising the connection structure according to claim 1.

13. A display panel, comprising the display substrate according to claim 12.

14. The display panel according to claim 13, further comprising a flexible circuitry board, wherein pins of the flexible circuitry board are bound to binding pins.

15. The display panel according to claim 14, wherein a distance between a first edge of each pin of the flexible circuitry board and a cutting edge of the flexible circuitry board is greater than or equal to 10 μm and less than or equal to 30 μm, the first edge is an edge of the pin close to the cutting edge, and the cutting edge is an edge of the flexible circuitry board closest to the first connection member.

16. A method for manufacturing the display panel according to claim 14, comprising enabling a flexible circuitry board to be bound to a display substrate through a binding pressure head.

17. The method according to claim 16, wherein a buffer material layer is arranged between the binding pressure head and the flexible circuitry board, and a thickness of the buffer material layer is greater than or equal to 100 μm and smaller than or equal to 150 μm.

18. A detection circuitry for the display panel according to claim 14—of 15, comprising a detection line and a detection unit, wherein the detection line is electrically coupled to a to-be-detected binding pin, and the detection unit is electrically coupled to the detection line and configured to determine where a short circuit occurs for the to-be-detected binding pin in accordance with a voltage across the detection line.

19. The detection circuitry according to claim 18, wherein the detection unit comprises a light-emitting diode, an anode of the light-emitting diode is electrically coupled to the detection line, and a cathode of the light-emitting diode is electrically coupled to a detection comparison voltage end, so as to determine whether the short circuit occurs for the to-be-detected binding pin in accordance with whether the light-emitting diode emits lights, wherein the detection comparison voltage end is configured to output a corresponding detection comparison voltage in accordance with the to-be-detected binding pin.

20. A display device, comprising the display panel according to claim 13.
